(19) United States
(12) Patent Application Publication
(10) Pub. No.: US 2018/0069099 A1
(43) Pub. Date: Mar. 8, 2018

(54) MANUFACTURE METHOD OF N TYPE THIN FILM TRANSISTOR

(71) Applicant: Wuhan China Star Optoelectronics Technology Co., Ltd., Wuhan City (CN)

(72) Inventor: Xiaojiang Yu, Wuhan City (CN)

(21) Appl. No.: 15/119,383

(22) PCT Filed: May 26, 2016
(86) PCT No.: PCT/CN2016/083566

§ 371 Date: Aug. 16, 2016

(30) Foreign Application Priority Data
Feb. 14, 2016 (CN) 201610085496.6

(51) Int. Cl. H01L 29/66; H01L 29/786; H01L 21/306

(52) U.S. Cl. CPC H01L 29/66757; H01L 29/78696; H01L 21/30604; H01L 29/78675

(57) ABSTRACT

The present invention provides a manufacture method of a N type thin film transistor. In the manufacture process, the chemical solution is employed to etch the channel region of the N type thin film transistor to raise a surface roughness of the low temperature polysilicon in the channel region of the N type thin film transistor, and thus to raise the surface defect density of the low temperature polysilicon in the channel region of the N type thin film transistor. Then, the threshold voltage of the manufactured N type thin film transistor moves toward the positive direction to ensure that the manufactured N type thin film transistor can be closed in time under the low voltage. The production efficiency is high and the production cost is low.

### FIELD OF THE INVENTION

The present invention relates to a display technology field, and more particularly to a manufacture method of a N type thin film transistor.

### BACKGROUND OF THE INVENTION

The flat panel display elements possess many merits of thin frame, power saving, no radiation, etc. and have been widely used. The present flat panel display elements at present mainly comprise the Liquid Crystal Display (LCD) and the Organic Light Emitting Display (OLED).

In the flat panel display, the Thin Film Transistor (TFT) is employed to be a switch element to control the operation of the pixel, or employed to be a drive element for driving the pixel. The thin film transistor generally can be categorized into two kinds, amorphous silicon (a-Si) and polysilicon (Poly-Si) according to the silicon thin film property.

Because the defect issue of the amorphous silicon itself, such as too many defects result in low on state current, low mobility, poor stability, which is restricted in application. For compensating the defect of the amorphous silicon itself and expanding the application field, the Low Temperature Poly-Silicon (LTPS) technology is born at the right moment.

Due to the atom arrangement rule of the Low Temperature Poly-Silicon, the mobility of the carrier is high (10-300 cm²/Vs). As being applied in the electronic element, such as the thin film transistors, the thin film transistor can have the higher drive current. Thus, in the manufacture process of the thin film transistor, the LTPS thin film is widely utilized for being the material of the active layer which is the core structure of the thin film transistor.

The flat panel display utilizing LTPS thin film transistor possesses advantages of high resolution, fast response, high brightness, high aperture ratio, et cetera. Because the silicon crystallization of the LTPS has better order than the amorphous silicon, it makes the electron mobility higher relatively above 100 times, and in the meantime, the peripheral driving circuit is manufactured on the glass substrate to achieve the objective of the system integration to save the space and the cost of the driving IC; meanwhile, cause of the driving IC circuit directly manufactured on the panel, the external connection points of the assembly can be can be diminished to raise the reliability. The maintenance is easier and the assembly process time can be shortened. Thus, the time schedule of the application system design is reduced and the design possibility is enlarged. It is more common that the N type thin film transistor (NTFT) is used on the flat panel display. For making the N type thin film transistor can be closed under the low voltage, the threshold voltage of the N type thin film transistor needs to be adjusted (moved from 1.0V to about 1.5V). In prior art, the ion implantation is generally used for adjusting the threshold voltage of the N type thin film transistor. Namely, low dose boron ion implantation is implemented to the polysilicon (Poly-si) of the channel region of the N type thin film transistor to adjust the threshold voltage of the N type thin film transistor.

Specifically, referring to FIG. 1-FIG. 3, the manufacture process of the N type thin film transistor in prior art is: first, referring to FIGS. 1-2, sequentially manufacturing a buffer layer 2 and a low temperature polysilicon layer 31 on the substrate 1 from bottom to top; coating a photoresist layer 5 on the low temperature polysilicon layer 31; and then implementing exposure, development to the photoresist layer 5 with a mask to define a channel region 32 on the low temperature polysilicon layer 31; then, implementing low dose boron (B) ion implantation to the channel region 32, and then removing the photoresist layer 5 on the low temperature polysilicon layer 31; next, referring to FIG. 3, implementing etching and ion doping to the low temperature polysilicon layer 31 to form an active layer 3; finally, sequentially manufacturing a gate insulation layer 6, a gate 7, an interlayer insulation layer 8 and a source/a drain 9 on the active layer 3 from bottom to top. In the aforesaid manufacture process of the N type thin film transistor, the hole carrier concentration of the polysilicon in the channel region 32 is adjusted by implanting boron ion in the channel region 32 to make the threshold voltage of the manufactured N type thin film transistor move toward the positive direction. However, such method has to be conducted in vacuum in the expensive ion implanter. The production efficiency is lower and the production cost is higher.

### SUMMARY OF THE INVENTION

An objective of the present invention is to provide a manufacture method of a N type thin film transistor. The method can adjust the threshold voltage of the N type thin film transistor, and ensure that the manufactured N type thin film transistor can be closed in time under the low voltage. The manufacture is simple, and the production efficiency is high, and the production cost is low.

For realizing the aforesaid objectives, the present invention provides a manufacture method of a N type thin film transistor, comprising steps of:

step 1, providing a substrate, sequentially manufacturing a buffer layer, a low temperature polysilicon layer and a silicon oxide layer on the substrate from bottom to top, wherein a surface layer of the low temperature polysilicon layer is oxidized to form a silicon oxide layer;

step 2, coating a photoresist layer on the low temperature polysilicon layer, and after employing a mask to implement exposure and development thereto, defining a channel region on the low temperature polysilicon layer;

step 3, employing chemical solution to etch the low temperature polysilicon layer in the channel region to remove the silicon oxide layer above the channel region, and etching the low temperature polysilicon in the channel region to raise a surface roughness of the low temperature polysilicon in the channel region;

step 4, implementing patterning and N type ion doping to the low temperature polysilicon layer to form an active layer;

step 5, sequentially manufacturing a gate insulation layer, a gate and an interlayer insulation layer on the active layer and the buffer layer from bottom to top, and patterning the gate insulation layer, the interlayer insulation layer and the silicon oxide layer with one photolithographic process to obtain two vias corresponding to two ends of the active layer;

step 6, forming a source/a drain on the interlayer insulation layer, wherein the source/the drain contact with the two ends of the active layer through the two vias.

Selectably, in the step 3, Tetramethylammonium hydroxide aqueous solution is employed to etch the low temperature polysilicon layer in the channel region.

Selectably, in the step 3, hydrogen peroxide is first employed to implement oxidation treatment to the low temperature polysilicon layer in the channel region, and then ammonium fluoride aqueous solution is employed to etch the low temperature polysilicon layer in the channel region.

All materials of the buffer layer, the gate insulation layer and the interlayer insulation layer are a stack combination of one or more of silicon oxide and silicon nitride.

In the step 4, the N type ion which is doped is phosphorus ion.

The active layer comprises the channel region in the middle and the N type ion doping regions at the two ends of the channel region.

In the step 1, a specific manufacture process of the low temperature polysilicon layer is: first, depositing an amorphous silicon on the buffer layer, and then implementing crystallization treatment to the amorphous silicon to manufacture the low temperature polysilicon layer.

Material of the gate and the source/the drain is a stack combination of one or more of molybdenum, aluminum and copper.

The present invention further provides a manufacture method of a N type thin film transistor, comprising steps of:

step 1, providing a substrate, and sequentially manufacturing a buffer layer and a low temperature polysilicon layer on the substrate from bottom to top, wherein a surface layer of the low temperature polysilicon layer is oxidized to form a silicon oxide layer;

step 2, coating a photoresist layer on the low temperature polysilicon layer, and after employing a mask to implement exposure and development thereto, defining a channel region on the low temperature polysilicon layer;

step 3, employing chemical solution to etch the low temperature polysilicon layer in the channel region to remove the silicon oxide layer above the channel region, and etching the low temperature polysilicon in the channel region to raise a surface roughness of the low temperature polysilicon in the channel region;

step 4, implementing patterning and N type ion doping to the low temperature polysilicon layer to form an active layer;

step 5, sequentially manufacturing a gate insulation layer, a gate and an interlayer insulation layer on the active layer and the buffer layer from bottom to top, and patterning the gate insulation layer, the interlayer insulation layer and the silicon oxide layer with one photolithographic process to obtain two vias corresponding to two ends of the active layer;

step 6, forming a source/a drain on the interlayer insulation layer, wherein the source/the drain contact with the two ends of the active layer through the two vias;

wherein all materials of the buffer layer, the gate insulation layer and the interlayer insulation layer are a stack combination of one or more of silicon oxide and silicon nitride;

wherein the active layer comprises the channel region in the middle and the N type ion doping regions at the two ends of the channel region.

The benefits of the present invention are: the present invention provides a manufacture method of a N type thin film transistor. In the manufacture process, the chemical solution is employed to etch the channel region of the N type thin film transistor to raise a surface roughness of the low temperature polysilicon in the channel region of the N type thin film transistor, and thus to raise the surface defect density of the low temperature polysilicon in the channel region of the N type thin film transistor. Then, the threshold voltage of the manufactured N type thin film transistor moves toward the positive direction to ensure that the manufactured N type thin film transistor can be closed in time under the low voltage. In comparison with prior art, the method can use the cheaper apparatus and can achieve the production of multiple substrates at the same time to reduce the production cost and raise the production efficiency.

### BRIEF DESCRIPTION OF THE DRAWINGS

In order to better understand the characteristics and technical aspect of the invention, please refer to the following detailed description of the present invention is concerned with the diagrams, however, provide reference to the accompanying drawings and description only and is not intended to be limiting of the invention.

In drawings,

FIG. 1 is a diagram of exposure implemented to a photoresist layer in the manufacture process of the N type thin film transistor according to prior art;

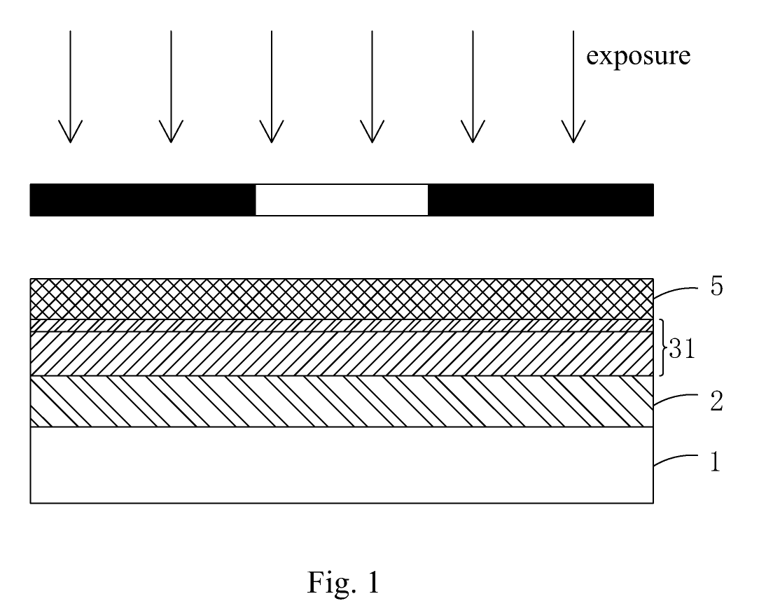

FIG. 2 is a diagram of ion doping implemented to a channel region in the manufacture process of the N type thin film transistor according to prior art;

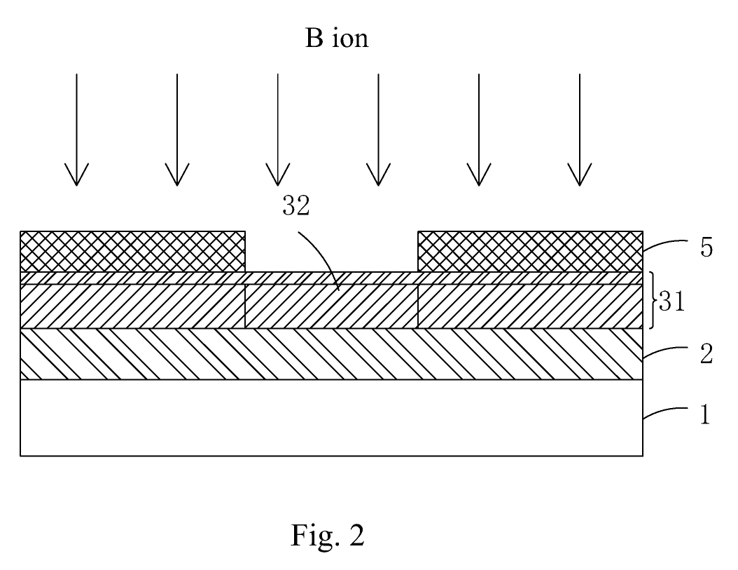

FIG. 3 is a structure diagram of the N type thin film transistor according to prior art;

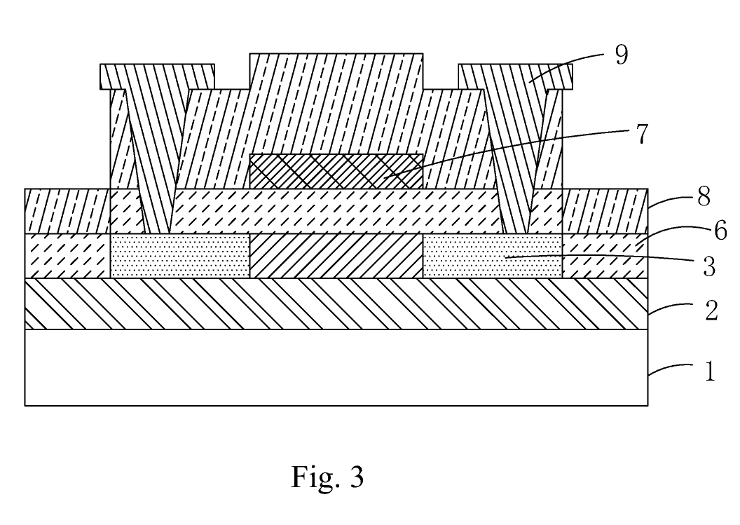

FIG. 4 is a flowchart diagram of a manufacture method of a N type thin film transistor according to the present invention;

FIG. 5 is a diagram of the step 1 of the manufacture method of the N type thin film transistor according to the present invention;

FIG. 6 is a diagram of the step 2 of the manufacture method of the N type thin film transistor according to the present invention;

FIG. 7 is a diagram of the first embodiment of the step 3 in the manufacture method of the N type thin film transistor according to the present invention;

FIG. 8 is a diagram of the second embodiment of the step 3 in the manufacture method of the N type thin film transistor according to the present invention;

FIG. 9 is a diagram of the step 4 of the manufacture method of the N type thin film transistor according to the present invention;

FIG. 10 is a diagram of the step 5 of the manufacture method of the N type thin film transistor according to the present invention;

FIG. 11 is a diagram of the step 6 of the manufacture method of the N type thin film transistor according to the present invention.

### DETAILED DESCRIPTION OF PREFERRED EMBODIMENTS

For better explaining the technical solution and the effect of the present invention, the present invention will be further described in detail with the accompanying drawings and the specific embodiments.

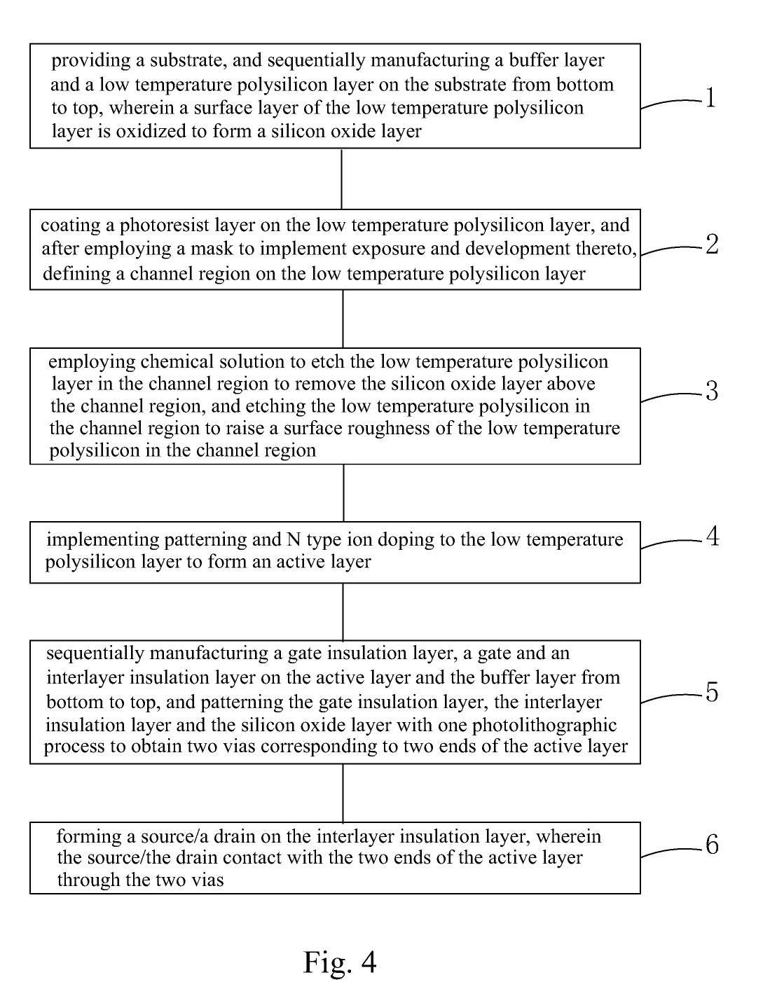

Please refer to FIG. 4. The present invention provides a manufacture method of a N type thin film transistor, comprising steps of:

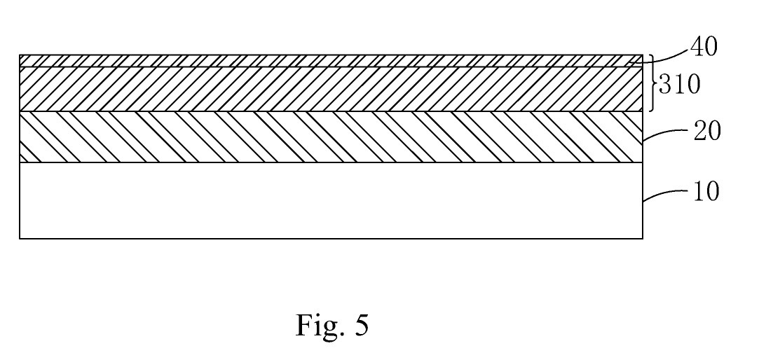

step 1, referring to FIG. 5, providing a substrate 10, and sequentially manufacturing a buffer layer 20 and a low temperature polysilicon layer 310 on the substrate 10 from bottom to top, wherein a surface layer of the low temperature polysilicon layer 310 is oxidized to form a silicon oxide layer 40.

Specifically, materials of the buffer layer 20 is a stack combination of one or more of silicon oxide and silicon nitride. A specific manufacture process of the low temperature polysilicon layer 310 is: first, depositing an amorphous silicon on the buffer layer 20, and then implementing crystallization treatment to the amorphous silicon to manufacture the low temperature polysilicon layer 310.

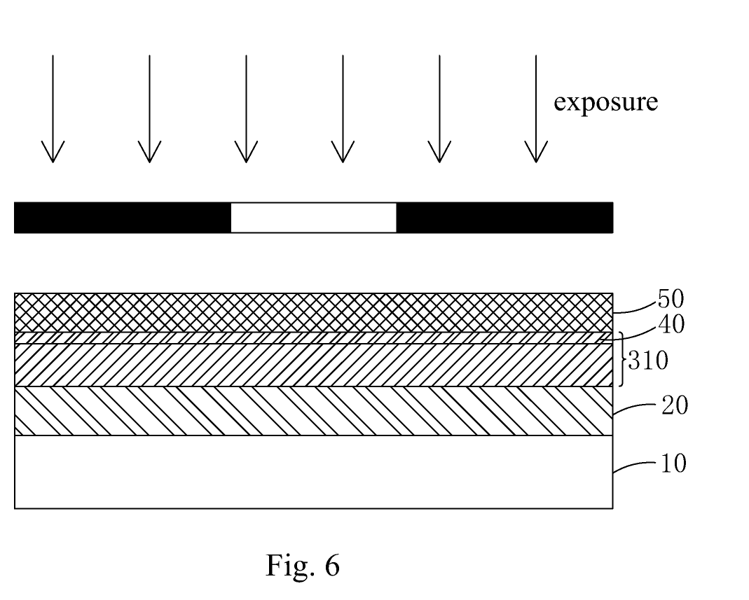

step 2, referring to FIG. 6, coating a photoresist layer 50 on the low temperature polysilicon layer 310, and after employing a mask to implement exposure and development thereto, defining a channel region 320 on the low temperature polysilicon layer 310.

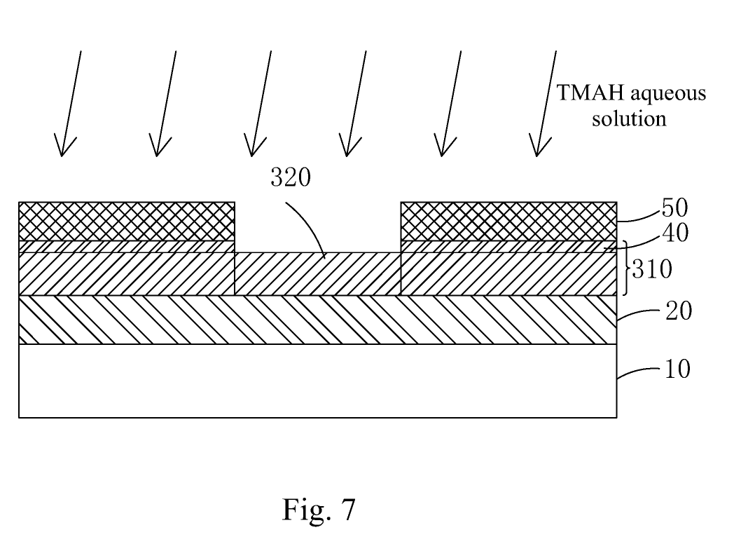

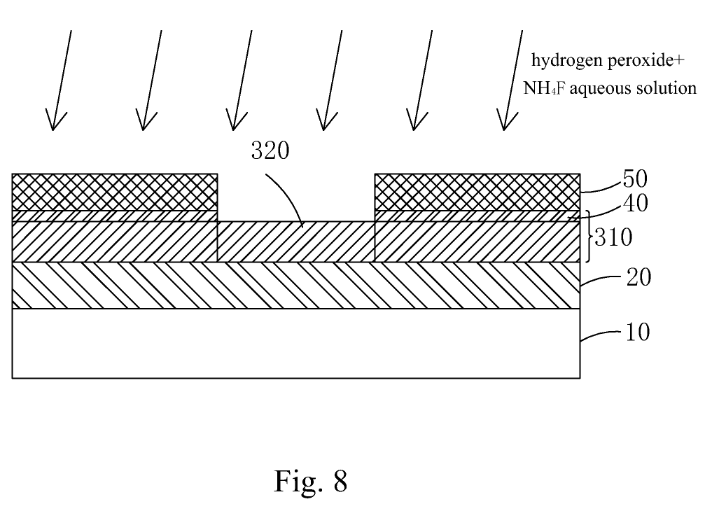

step 3, referring to FIG. 7 and FIG. 8, employing chemical solution to etch the low temperature polysilicon layer 310 in the channel region 320 to remove the silicon oxide layer 40 above the channel region 320, and etching the low temperature polysilicon in the channel region 320 to raise a surface roughness of the low temperature polysilicon in the channel region 320.

Selectably, referring to FIG. 7, in the step 3, Tetramethylammonium hydroxide (TMAH) aqueous solution is employed to etch the low temperature polysilicon layer 310 in the channel region 320. Preferably, the mass ratio of the Tetramethylammonium hydroxide in the Tetramethylammonium hydroxide aqueous solution is 5%-30%.

Selectably, referring to FIG. 8, in the step 3, hydrogen peroxide is first employed to implement oxidation treatment to the low temperature polysilicon layer 310 in the channel region 320 to make the thickness of the silicon oxide layer 40, which is the surface layer, more uniform and then ammonium fluoride (NH₄F) aqueous solution is employed to etch the low temperature polysilicon layer 310 in the channel region 320. The hydrogen peroxide and the NH₄F aqueous solution can be recycled for many times. Preferably, the volume ratio of the perhydrol (H₂O₂) in the hydrogen peroxide is 20%-80%; the mass ratio of the ammonium fluoride aqueous solution is 3%-20%.

Particularly, the chemical solution is employed to etch the channel region of the N type thin film transistor. A surface roughness of the low temperature polysilicon in the channel region of the N type thin film transistor can be raised, and thus to raise the surface defect density of the low temperature polysilicon in the channel region of the N type thin film transistor. Then, the threshold voltage of the manufactured N type thin film transistor moves toward the positive direction to ensure that the manufactured N type thin film transistor can be closed in time under the low voltage. In comparison with the method of adjusting the NTFT threshold voltage with boron ion implantation according to prior art, the apparatus used by the chemical solution etching is cheaper and the production of multiple substrates at the same time can be achieved to reduce the production cost and raise the production efficiency.

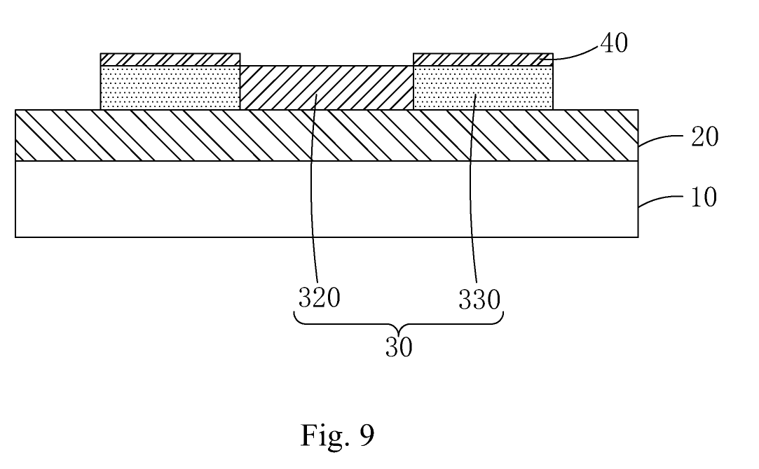

step 4, referring to FIG. 9, implementing patterning and N type ion doping to the low temperature polysilicon layer 310 to form an active layer 30.

Specifically, in the step 4, the N type ion which is doped is phosphorus ion. The active layer 30 comprises the channel region 320 in the middle and the N type ion doping regions 330 at the two ends of the channel region 320. The channel region 320 is low temperature polysilicon which has not been implemented with ion doping.

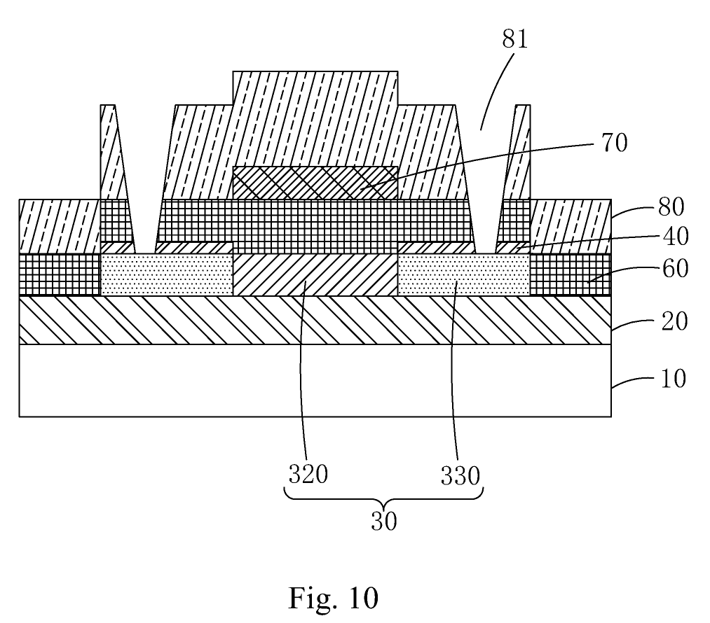

step 5, referring to FIG. 10, sequentially manufacturing a gate insulation layer 60, a gate 70 and an interlayer insulation layer 80 on the active layer 30 and the buffer layer 20 from bottom to top, and patterning the gate insulation layer 60, the interlayer insulation layer 80 and the silicon oxide layer 40 with one photolithographic process to obtain two vias 81 corresponding to two ends of the active layer 30.

Specifically, both materials of the gate insulation layer 60 and the interlayer insulation layer 80 are a stack combination of one or more of silicon oxide and silicon nitride.

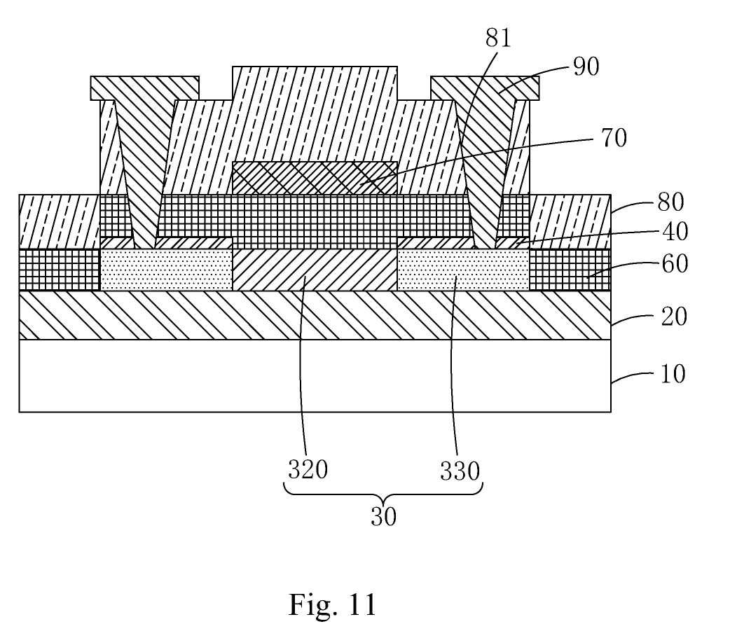

step 6, referring to FIG. 11, forming a source/a drain 90 on the interlayer insulation layer 80, wherein the source/the drain 90 contact with the two ends of the active layer 30 through the two vias 81.

Specifically, material of the gate 70 and the source/the drain 90 is a stack combination of one or more of molybdenum, aluminum and copper.

In conclusion, the present invention provides a manufacture method of a N type thin film transistor. In the manufacture process, the chemical solution is employed to etch the channel region of the N type thin film transistor to raise a surface roughness of the low temperature polysilicon in the channel region of the N type thin film transistor, and thus to raise the surface defect density of the low temperature polysilicon in the channel region of the N type thin film transistor. Then, the threshold voltage of the manufactured N type thin film transistor moves toward the positive direction to ensure that the manufactured N type thin film transistor can be closed in time under the low voltage. In comparison with prior art, the method can use the cheaper apparatus and can achieve the production of multiple substrates at the same time to reduce the production cost and raise the production efficiency.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A manufacture method of a N type thin film transistor, comprising steps of:
step 1, providing a substrate, and sequentially manufacturing a buffer layer and a low temperature polysilicon layer on the substrate from bottom to top, wherein a surface layer of the low temperature polysilicon layer is oxidized to form a silicon oxide layer;
step 2, coating a photoresist layer on the low temperature polysilicon layer, and after employing a mask to implement exposure and development thereto, defining a channel region on the low temperature polysilicon layer;
step 3, employing chemical solution to etch the low temperature polysilicon layer in the channel region to remove the silicon oxide layer above the channel region, and etching the low temperature polysilicon in the channel region to raise a surface roughness of the low temperature polysilicon in the channel region;
step 4, implementing patterning and N type ion doping to the low temperature polysilicon layer to form an active layer;
step 5, sequentially manufacturing a gate insulation layer, a gate and an interlayer insulation layer on the active layer and the buffer layer from bottom to top, and patterning the gate insulation layer, the interlayer insulation layer and the silicon oxide layer with one photolithographic process to obtain two vias corresponding to two ends of the active layer;
step 6, forming a source/a drain on the interlayer insulation layer, wherein the source/the drain contact with the two ends of the active layer through the two vias.

2. The manufacture method of the N type thin film transistor according to claim 1, wherein in the step 3, Tetramethylammonium hydroxide aqueous solution is employed to etch the low temperature polysilicon layer in the channel region.

3. The manufacture method of the N type thin film transistor according to claim 1, wherein in the step 3, hydrogen peroxide is first employed to implement oxidation treatment to the low temperature polysilicon layer in the channel region, and then ammonium fluoride aqueous solution is employed to etch the low temperature polysilicon layer in the channel region.

4. The manufacture method of the N type thin film transistor according to claim 1, wherein all materials of the buffer layer, the gate insulation layer and the interlayer insulation layer are a stack combination of one or more of silicon oxide and silicon nitride.

5. The manufacture method of the N type thin film transistor according to claim 1, wherein in the step 4, the N type ion which is doped is phosphorus ion.

6. The manufacture method of the N type thin film transistor according to claim 1, wherein the active layer comprises the channel region in the middle and the N type ion doping regions at the two ends of the channel region.

7. The manufacture method of the N type thin film transistor according to claim 1, wherein in the step 1, a specific manufacture process of the low temperature polysilicon layer is: first, depositing an amorphous silicon on the buffer layer, and then implementing crystallization treatment to the amorphous silicon to manufacture the low temperature polysilicon layer.

8. The manufacture method of the N type thin film transistor according to claim 1, wherein material of the gate and the source/the drain is a stack combination of one or more of molybdenum, aluminum and copper.

9. A manufacture method of a N type thin film transistor, comprising steps of:
step 1, providing a substrate, and sequentially manufacturing a buffer layer and a low temperature polysilicon layer on the substrate from bottom to top, wherein a surface layer of the low temperature polysilicon layer is oxidized to form a silicon oxide layer;
step 2, coating a photoresist layer on the low temperature polysilicon layer, and after employing a mask to implement exposure and development thereto, defining a channel region on the low temperature polysilicon layer;
step 3, employing chemical solution to etch the low temperature polysilicon layer in the channel region to remove the silicon oxide layer above the channel region, and etching the low temperature polysilicon in the channel region to raise a surface roughness of the low temperature polysilicon in the channel region;
step 4, implementing patterning and N type ion doping to the low temperature polysilicon layer to form an active layer;
step 5, sequentially manufacturing a gate insulation layer, a gate and an interlayer insulation layer on the active layer and the buffer layer from bottom to top, and patterning the gate insulation layer, the interlayer insulation layer and the silicon oxide layer with one photolithographic process to obtain two vias corresponding to two ends of the active layer;
step 6, forming a source/a drain on the interlayer insulation layer, wherein the source/the drain contact with the two ends of the active layer through the two vias;
wherein all materials of the buffer layer, the gate insulation layer and the interlayer insulation layer are a stack combination of one or more of silicon oxide and silicon nitride;
wherein the active layer comprises the channel region in the middle and the N type ion doping regions at the two ends of the channel region.

10. The manufacture method of the N type thin film transistor according to claim 9, wherein in the step 3, Tetramethylammonium hydroxide aqueous solution is employed to etch the low temperature polysilicon layer in the channel region.

11. The manufacture method of the N type thin film transistor according to claim 9, wherein in the step 3, hydrogen peroxide is first employed to implement oxidation treatment to the low temperature polysilicon layer in the channel region, and then ammonium fluoride aqueous solution is employed to etch the low temperature polysilicon layer in the channel region.

12. The manufacture method of the N type thin film transistor according to claim 9, wherein in the step 4, the N type ion which is doped is phosphorus ion.

13. The manufacture method of the N type thin film transistor according to claim 9, wherein in the step 1, a specific manufacture process of the low temperature polysilicon layer is: first, depositing an amorphous silicon on the buffer layer, and then implementing crystallization treatment to the amorphous silicon to manufacture the low temperature polysilicon layer.

14. The manufacture method of the N type thin film transistor according to claim 9, wherein material of the gate and the source/the drain is a stack combination of one or more of molybdenum, aluminum and copper.
